(19) United States
(12) Patent Application Publication
(10) Pub. No.: US 2008/0258250 A1
(43) Pub. Date: Oct. 23, 2008

(54) Solid-state image capturing device, method of manufacturing the same, and electronic information device

(75) Inventor: Akira Uenishi, Fukuyama-shi (JP)

Correspondence Address: Edwards Angell Palmer & Dodge LLP, P.O. Box 55874, Boston, MA, 02205, US

(73) Assignee: Sharp Kabushiki Kaisha, Osaka (JP)

(21) Appl. No.: 12/081,651

(22) Filed: Apr. 18, 2008

(30) Foreign Application Priority Data
Apr. 19, 2007 (JP) 2007-111013

(51) Int. Cl. H01L 31/0232; H01L 31/18

(52) U.S. Cl. 257/432; 438/70; 257/E31.127

(57) ABSTRACT

A solid-state image capturing device is provided, in which a multilayered wiring section having a plurality of wiring layers laminated via respective interlayer insulation films is provided on a semiconductor substrate or a semiconductor region formed on the substrate where a plurality of light receiving sections for photoelectrically converting a subject light are arranged in matrix in a pixel section; and the interlayer insulation films in a pixel section are evenly engraved, so that the pixel section of the substrate is thinner than a peripheral circuit section; and a plurality of light receiving sections and respective microlenses facing with each other are arranged on the bottom surface of the engraved portion of the interlayer insulation film.

This Nonprovisional Application claims priority under 35 U.S.C. §119(a) on Patent Application No. 2007-111013 filed in Japan on Apr. 19, 2007, the entire contents of which are hereby incorporated by reference.

### BACKGROUND OF THE INVENTION

1. Field of the Invention

The present invention relates to a solid-state image capturing device, such as CMOS image sensor, a manufacturing method of the solid-state image capturing device, and an electronic information device, such as digital camera and cell phone device equipped with camera, using the solid-state image capturing device as an image capturing section thereof.

2. Description of the Related Art

Conventionally, Focal distance has been significant issue in terms of optical characteristics of a solid-state image capturing device, such as a CMOS image sensor and the like.

In general, a conventional solid-state image capturing device is configured with a microlens that is arranged in such a manner to face a photo diode and a focal point of the microlens is set near the surface of the photo diode, so that incident light is efficiently taken in as a signal charge by a photo diode as a light receiving section.

FIG. 10 is a longitudinal cross-sectional view showing an essential structure of a conventional solid-state image capturing device.

In FIG. 10, a conventional solid-state image capturing device 100 is configured with a gate electrode 103 adjacent to a photo diode 102, and the gate electrode reads out a signal charge photoelectrically converted in the photo diode 102 above a region of a pixel section on a substrate 101, in which a plurality of photo diodes as light receiving sections for photoelectrically converting a subject light are arranged in two dimensional matrix. The pixel section is configured with a plurality of light receiving sections, which are a plurality of unit pixels. A multilayered wiring section is provided on the substrate 101, where a plurality of wiring layers 104, 106 and 108 (3 layers in this case) are respectively laminated via interlayer insulation films 105, 107 and 109 in between adjacent layers. The wiring layers 104, 106 and 108 are provided above each gate electrode 103, so that above the photo diodes 102 are open and light enters each photo diode 102. On the upper most interlayer insulation film 109, a protective film 110 and an interlayer film 111, a color filter 112, and microlenses 113 via the protective film 110 and the interlayer film 111 are laminated in this order. Each of the microlenses 113 is arranged in such a manner to face each photo diode 101.

With respect to the conventional solid-state image capturing device 100 that is configured as described above, a method for adjusting the thickness of the interlayer insulation films 105, 107 and 109 as well as the interlayer film 111 is generally used in order to adjust focal distance.

In recent years, microlenses have needed to be down sized even more to keep up with the miniaturization of solid-state image capturing devices. Thus, the curvature radius of the lens becomes smaller, and therefore, a focal distance becomes shorter. On the other hand, the interlayer insulation films become thicker from the requirement of a multilayered wiring section, and therefore, the distance between the lens and the substrate tends to increase. As a result, it is difficult to adjust the focal distance due to the thickness of the interlayer insulation film and the interlayer film, causing a degradation of the optical characteristics to be worse.

In order to solve the problem, Reference 1, for example, proposes the provision of a solid-state image capturing device that has an optical waveguide above a photo diode as a light receiving section so that light from the lens is efficiently taken into the photo diode.

FIG. 11 is a longitudinal cross-sectional view showing an essential structure of a conventional solid-state image capturing device that is disclosed in Reference 1.

In FIG. 11, with respect to a conventional solid-state image capturing device 200, a plurality of photo diodes 202 are arranged in a two dimensional matrix, and diffusion layers 203 are provided so as to be adjacent to the photo diodes 202 at a specified interval. Element dividing regions 204 are provided on the surface section of a silicon substrate 201 to divide from adjacent unit pixels. A gate electrode 206 is provided via a gate insulation film 205 above a region between the photodiode 202 and the diffusion layer 203 on the silicon substrate 201 so as to be adjacent to the photo diode 202 in a plane view; and another gate electrode 206a is provided above one element dividing region 204. A MOS transistor is configured with the diffusion layer 203, the gate insulation film 205 and the gate electrode 206, allowing of charge-transferring a signal charge from the photodiode 202 to the diffusion layer 203.

A multilayered wiring section is provided on the substrate 201, where interlayer insulation film 207, 209, 211 and 213, and a plurality of wiring layers 208, 210 and 212 (three layers in this case) are alternatively laminated on top of another. Contact sections 214 are provided in the interlayer insulation films 207, 209 and 211 that configure the multilayered wiring section to electrically connect between the silicon substrate 201 and the wiring layer 208, between the wiring layer 208 and the wiring layer 210, and between the wiring layer 210 and the wiring layer 212. In addition, an opening 215 is provided in the interlayer insulation films 207, 209, 211 and 213 and above the photo diode 202 that functions as a light receiving section. A protective film 216 is provided on the interlayer insulation film 213, and a reflective film 217 is provided on the inner wall of the opening 215 via the protective film 216. A flattened insulation film 218 is provided thereon to fill inside the opening 215 and make it flattened, and a color filter 219 is provided on the flattened insulation film 218. Microlenses 220 are provided on the color filter 219 in such a manner to face respective photo diodes 202.

According to this structure, even if the distance between the microlens 220 and the photo diode 202 is too great due to the provision of the multilayered wiring section, and the focal point of the microlens 220 is not set near the surface of the photo diode 202, incident light is reflected by the reflective film 217 so that the reflective light is guided through the optical waveguide to the photo diode 202, thereby condensing the light efficiently in the photo diode 202 functioning as a light receiving section.

Reference 1: Japanese Laid-Open Publication No. 2003-197886.

### SUMMARY OF THE INVENTION

The prior art described above, however, has the following problems.

First, with respect to the prior art shown in FIG. 10 and the conventional solid-state image capturing device that adjusts the focal distance with the thickness of the interlayer insulation films 105, 107 and 109 as well as the interlayer film 111, the focal distance of the microlens 113 becomes shorter with the miniaturization of a solid-state image capturing device, and the distance between the lens and the substrate thus becomes greater due to the interposed multilayered wiring section, causing a degradation of the optical characteristics.

With respect to the prior art of Reference 1 shown in FIG. 11, which is proposed to solve this problem described above, an optical waveguide is provided on a photo diode 202 functioning as a light receiving section. However, due to the provision of the optical waveguide as described above, the number of the manufacturing steps significantly increases compared to the method for adjusting the focal distance of the microlens by adjusting the thickness of the interlayer insulation films and the interlayer film as shown in FIG. 10.

The present invention solves the problems described above. The objective of the present invention is to provide a solid-state image capturing device which contains a multilayered wiring structure while shortening the distance between the lens and the substrate in a simple manner, thereby improving optical characteristics in light receiving. It is also an object of the present invention to provide the method for manufacturing the solid-state image capturing device; and an electronic information device using the solid-state image capturing device as an image capturing section.

The present invention provides a solid-state image capturing device, in which a multilayered wiring section having a plurality of wiring layers laminated via respective interlayer insulation films is provided on a semiconductor substrate or a semiconductor region formed on the substrate where a plurality of light receiving sections for photoelectrically converting a subject light are arranged in matrix in a pixel section; and the interlayer insulation films in a pixel section are evenly engraved, so that the pixel section of the substrate is thinner than a peripheral circuit section; and microlenses are arranged to face the plurality of light receiving sections respectively on the bottom surface of the engraved portion of the interlayer insulation film, thereby achieving the objective described above.

Preferably, in a solid-state image capturing device according to the present invention, a layer of air is provided instead of some of the interlayer insulation films. In addition, preferably, in a solid-state image capturing device according to the present invention, the plurality of wiring layers are supported by contact sections on the semiconductor substrate or the semiconductor region formed on the substrate and by contact sections between the wiring sections, so that the plurality of wiring layers are configured in the multilayered wiring section.

Still preferably, in a solid-state image capturing device according to the present invention, the amount of engraving for the interlayer insulation film is adjusted in such a manner that the focal point of the microlens is set on a surface of the light receiving section.

Still preferably, in a solid-state image capturing device according to the present invention, a wiring pattern is arranged in a depth region of the interlayer insulation films engraved only from a periphery of the pixel section view to a peripheral section in a plane.

Still preferably, in a solid-state image capturing device according to the present invention, the wiring layers, which the engraving for the interlayer insulation films reach, are formed into a stepwise wiring pattern such that an end portion, adjacent to the pixel section, of the peripheral section becomes more distant in sequence from the pixel section as heading from a lower layer to an upper layer.

Still preferably, in a solid-state image capturing device according to the present invention, a periphery end of the engraved portion of the interlayer insulation films in a plane view is formed in a stepwise multi level form in accordance with the stepwise wiring pattern.

Still preferably, in a solid-state image capturing device according to the present invention, a periphery end of the engraved portion of the interlayer insulation films is formed in a taper form in such a manner that the engraved portion in a cross-sectional form is widened upwardly.

Still preferably, in a solid-state image capturing device according to the present invention, a protective film and an interlayer film are formed in this order on the bottom surface of the engraved portion of the interlayer insulation films; and color filters for respective colors are provided in such a manner to face the respective plurality of light receiving sections; and the microlenses are provided in such a manner to face the respective plurality of light receiving sections and the respective color filters for respective colors.

Still preferably, in a solid-state image capturing device according to the present invention, in the peripheral section, a first interlayer insulation film, a first wiring layer, a second interlayer insulation film, a second wiring layer, a third interlayer insulation film, a third wiring layer and a fourth interlayer insulation film are provided in this order from the bottom as the multilayered wiring section; and only the first wiring layer is provided in the pixel section; and the second interlayer insulation film, the third interlayer insulation film and the fourth interlayer insulation film are engraved up to halfway into the second interlayer insulation film as the engraved portion.

Still preferably, in a solid-state image capturing device according to the present invention, in the peripheral section, a first interlayer insulation film, a first wiring layer, a second interlayer insulation film, a second wiring layer, a third interlayer insulation film, a third wiring layer and a fourth interlayer insulation film are provided in this order from the bottom as the multilayered wiring section; and only the first wiring layer and the second wiring layer are provided in the pixel section; and the third interlayer insulation film and the fourth interlayer insulation film are engraved up to halfway into the third interlayer insulation film as the engraved portion.

Still preferably, in a solid-state image capturing device according to the present invention, in the peripheral section, a first interlayer insulation film, a first wiring layer, a second interlayer insulation film, a second wiring layer, a third interlayer insulation film, a third wiring layer, a fourth interlayer insulation film, a fourth wiring layer and a fifth interlayer insulation film are provided in this order from the bottom as the multilayered wiring section; and only the first wiring layer and the second wiring layer are provided in the pixel section; and the third interlayer insulation film, the fourth interlayer insulation film and the fifth interlayer insulation film are engraved up to halfway into the third interlayer insulation film as the engraved portion.

Still preferably, in a solid-state image capturing device according to the present invention, in the peripheral section, a first interlayer insulation film, a first wiring layer, a second interlayer insulation film, a second wiring layer, a third interlayer insulation film, a third wiring layer, a fourth interlayer Insulation film, a fourth wiring layer and a fifth interlayer insulation film are provided in this order from the bottom as the multilayered wiring section; and only the first wiring layer is provided in the pixel section; and the second interlayer insulation film, the third interlayer insulation film, the fourth interlayer insulation film and the fifth interlayer insulation film are engraved up to halfway into the second interlayer insulation film as the engraved portion.

Still preferably, in a solid-state image capturing device according to the present invention, in the peripheral section, a first interlayer insulation film, a first wiring layer, a second interlayer insulation film, a second wiring layer, a third interlayer insulation film, a third wiring layer, a fourth interlayer insulation film, a fourth wiring layer and a fifth interlayer insulation film are provided in this order from the bottom as the multilayered wiring section; and only the first wiring layer, the second wiring layer and the third wiring layer are provided in the pixel section; and the fourth interlayer insulation film and the fifth interlayer insulation film are engraved up to halfway into the fourth interlayer insulation film as the engraved portion.

Still preferably, in a solid-state image capturing device according to the present invention, in the peripheral section, a first wiring layer to an Nth (an integer of greater or equal to 3) wiring layer are provided as the multilayered wiring section with a first interlayer insulation film to an (N+1)th interlayer insulation film inserted respectively in between; and wiring layers of fewer number than Nth layers are provided in the pixel section; and interlayer insulation films that do not include the wiring layers are engraved as the engraved portion.

Still preferably, in a solid-state image capturing device according to the present invention, each of the wiring layers in the pixel section is arranged in such a manner that each wiring layer is divided and put together via an insulation film in a longitudinal direction and/or a transverse direction.

A method for manufacturing a solid-state image capturing device according to the present invention comprises: a multilayered wiring section forming step of forming a multilayered wiring section by laminating a plurality of wiring layer and interlayer insulation films alternatively on top of another on a semiconductor substrate or a semiconductor region formed on the substrate where a plurality of light receiving sections for photoelectrically converting a subject light are arranged in matrix in a pixel section; an interlayer insulation film engraving step of evenly engraving a region of the interlayer insulation films that do not include the wiring layers in the pixel section so that interlayer insulation films in the pixel section are formed thinner than a peripheral section of the pixel section; and a microlens forming step of forming microlenses on the bottom surface of the engraved portion of the interlayer insulation film in such a manner that the microlenses face the respective plurality of light receiving sections, thereby achieving the objective described above.

Preferably, in a method for manufacturing a solid-state image capturing device according to the present invention, the multilayered wiring section forming step forms a wiring pattern in a depth region of the interlayer insulation films engraved only from a periphery of the pixel section to a peripheral section in a plane view.

Still preferably, in a method for manufacturing a solid-state image capturing device according to the present invention, in the multilayered wiring section forming step, the wiring layers, which engraving for the interlayer insulation films reach, are formed into a stepwise wiring pattern such that the stepwise wiring pattern becomes more distant in sequence from the pixel section as heading from a lower layer to an upper layer.

Still preferably, in a method for manufacturing a solid-state image capturing device according to the present invention, in the interlayer insulation film engraving step, the amount of engraving is adjusted in such a manner that the focal point of the microlens is set on a surface of the light receiving section.

Still preferably, in a method for manufacturing a solid-state image capturing device according to the present invention, in the interlayer insulation film engraving step, the interlayer insulation films are engraved by self-alignment with the stepwise wiring pattern as a mask, so that a periphery end of the engraved portion of the interlayer insulation films in a plane view is formed in a stepwise multi level form in accordance with the stepwise wiring pattern.

Still preferably, in a method for manufacturing a solid-state image capturing device according to the present invention, a periphery end of the engraved portion of the interlayer insulation films is etched in the longitudinal and transverse directions by isotropic etching to form a taper form in such a manner that the engraved portion in a cross-sectional form is widened upwardly.

Still preferably, a method for manufacturing a solid-state image capturing device according to the present invention further includes a step of forming a protective film and an interlayer film in this order on the bottom surface of the engraved portion of the interlayer insulation film subsequent to the interlayer insulation film engraving step, and a color filter forming step of forming color filters for respective colors on the interlayer film in such a manner to face the respective plurality of light receiving sections; and

wherein the microlens forming step forms the microlenses on the color filters in such a manner to face the respective plurality of light receiving sections and the respective color filters for respective colors.

Still preferably, in a method for manufacturing a solid-state image capturing device according to the present invention, the interlayer insulation film engraving step engraves an interlayer insulation film by dry etching or wet etching.

An electronic information device of the present invention uses the solid-state image capturing device according to the present invention as an image input section thereof, thereby achieving the objective described above.

Hereinafter, the functions of the present invention having the structures described above will be described.

According to the present invention, interlayer insulation films in a pixel section are evenly engraved and microlenses are arranged in that engraved portion, so that the distance between the lens and the substrate can be significantly shortened. The amount of the engraving for the interlayer insulation films is adjusted in such a way that the focal point of the lens comes at the surface of the light receiving section. As a result, such a configuration allows of obtaining a multilayered wiring structure while significantly shortening the distance between the lens and the substrate in a simple manner.

Dry etching and wet etching can be used as a method for engraving the interlayer insulation films. However, the method using dry etching for the wiring layers, difference in vertical levels may occur due to their aligned ends, which leads to a high probability of occurrence of a striation (the state of being striated, which may cause uneven application) that indicates an inferior application of a microlens material by spin coating. Accordingly, it is considered difficult, in this case, to manufacture. It is also conceivable to provide a taper form by wet etching so as to reduce the degree of the difference in vertical levels. However, HF is used in general for wet etching, and it is necessary to secure a distance margin between the engraved portion and the wirings, resulting in a smaller region for wirings.

Therefore, it is preferable to form the engraved portion of the interlayer insulation films using the following method. That is, a wiring pattern for a wiring layer that the bottom of the engraved portion of the interlayer insulation films reaches is set in such a way that the wiring pattern is not provided in a pixel section, and the wiring pattern is formed into a stepwise wiring pattern such that the stepwise wiring pattern becomes more distant in sequence from the pixel section as heading from a lower layer to an upper layer. The interlayer insulation films are engraved by self-alignment with the stepwise wiring pattern as a mask, so that a periphery end of the engraved portion of the interlayer insulation films in a plane view is formed in a stepwise multi level form in accordance with the stepwise wiring pattern, thereby preventing the difference in vertical levels.

Thus, according to the present invention, the engraving of the interlayer insulation films in the pixel section allows of significantly shortening the distance between the lens and substrate while maintaining the multilayered wiring structure and improves optical characteristics. Further, the engraved portion of the interlayer insulation films is formed by the self-alignment engraving using the wiring pattern in such a manner that the engraved end is formed in a stepwise multi level form widening upwardly, thereby reducing an occurrence of a striation. Further, Self-alignment engraving allows of reducing a region where wiring pattern can not be formed in the peripheral section of the pixel section (allows of reducing the distance margin between the engraved portion and the wiring)

These and other advantages of the present invention will become apparent to those skilled in the art upon reading and understanding the following detailed description with reference to the accompanying figures.

### BRIEF DESCRIPTION OF THE DRAWINGS

FIG. 1 is a longitudinal cross-sectional view showing an essential structure of a solid-state image capturing device according to Embodiment 1 of the present invention.

FIGS. 2(a)-(c) are longitudinal cross-sectional views respectively showing a manufacturing step up to and including a step of forming an engraved portion in the solid-state image capturing device according to Embodiment 1 of the present invention.

FIGS. 3(a) and (b) are longitudinal cross-sectional views respectively showing a manufacturing step up to and including a step of forming a microlens in the solid-state image capturing device according to Embodiment 1 of the present invention.

FIGS. 4(a)-(c) are longitudinal cross-sectional views respectively showing another exemplary step of forming an engraved portion in a manufacturing step of a solid-state image capturing device according to a reference example of a case where an engraved portion with a difference in a vertical level is formed.

FIGS. 5(a)-(c) are longitudinal cross-sectional views showing a case where an engraved portion is formed by wet etching in a manufacturing step of a solid-state image capturing device according to a variation of Embodiment 1 of the present invention.

FIGS. 6(a)-(c) are longitudinal cross-sectional views respectively showing a manufacturing step up to and including a step of forming an engraved portion in the solid-state image capturing device according to Embodiment 2 of the present invention.

FIGS. 7(a) and (b) are longitudinal cross-sectional views respectively showing a manufacturing step up to and including a step of forming a microlens in the solid-state image capturing device according to Embodiment 2 of the present invention.

FIGS. 8(a)-(c) are longitudinal cross-sectional views respectively showing a manufacturing step up to and including a step of forming an engraved portion in the solid-state image capturing device according to Embodiment 3 of the present invention.

FIGS. 9(a) and (b) are longitudinal cross-sectional views respectively showing a manufacturing step up to and including a step of forming a microlens in the solid-state image capturing device according to Embodiment 3 of the present invention.

FIG. 10 is a longitudinal cross-sectional view showing an essential structure of a conventional solid-state image capturing device.

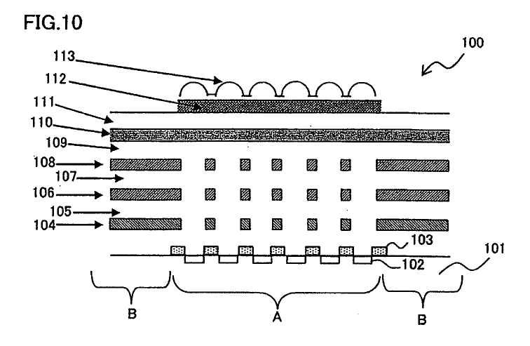

FIG. 11 is a longitudinal cross-sectional view showing an essential structure of a conventional solid-state image capturing device disclosed in Reference 1.

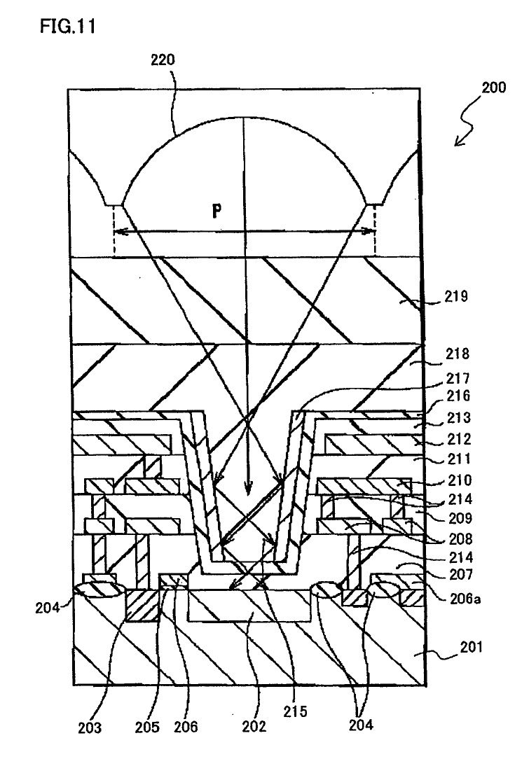

FIG. 12 is a block diagram showing an exemplary schematic structure of an electronic information device according to Embodiment 4 of the present invention using the solid-state image capturing apparatus as an image capturing section, the electronic information device including any one of the solid-state image capturing devices in Embodiments 1-3.

1 semiconductor substrate

2 photo diode (light receiving section)

3 gate electrode

4, 4A, 4B, 6, 6A, 8 wiring

5, 5A, 5B, 7, 9 interlayer insulation film

10 protective film

11 interlayer film

12 color filter

13 microlens

14 resist pattern

90 electronic information device

91 solid-state image capturing apparatus

92 memory section

93 display section

94 communication section

95 image output section

A pixel section

B peripheral circuit section

D opening

T, T1-T4 engraved portion

### DESCRIPTION OF THE PREFERRED EMBODIMENTS

Embodiments 1-4 of a solid-state image capturing device according to the present invention and a method of manufacturing the solid-state image capturing device will be described in detail with reference to the accompanying drawings.

### Embodiment 1

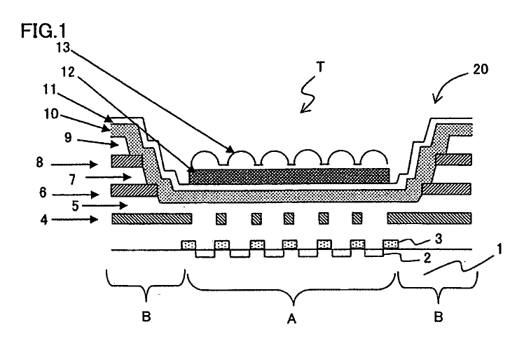

FIG. 1 is a longitudinal cross-sectional view showing an essential structure of a solid-state image capturing device according to Embodiment 1 of the present invention.

In FIG. 1, a solid-state image capturing device 20 according to Embodiment 1 includes: a pixel section A, in which a large number of unit pixels are arranged on a semiconductor substrate 1 (or on a semiconductor region provided on the substrate), and a peripheral circuit section B, which includes controllers and the like for outputting a control signal to read out a signal from each unit pixel such as logic circuit, shift resistor, driver circuit and clock circuit (there is also a case where DSP is included) in the periphery of the pixel section A.

A plurality of photo diodes 2 are arranged in a two dimensional matrix in the pixel section A, and a gate electrode 3 is provided adjacent to the photo diode 2 for reading out a signal charge that is photoelectrically converted from a subject light in the photo diode 2 functioning as a light receiving section.

A multilayered wiring section is provided in the peripheral circuit section B on the semiconductor substrate 1, where a plurality of wiring layers 4, 6, 8 and interlayer insulation films 5, 7, 9 are laminated alternately one on top of another. The multi layered wiring section is made of a metal material, such as aluminum, and, in the pixel section A, the multilayered wiring section is a wiring that is electrically connected with a terminal of a transistor (MOS transistor) that configures a readout circuit for amplifying and reading out a signal charge generated at the photo diode 2 for each unit pixel. In addition, in the peripheral circuit section B, the multilayered wiring section is a wiring that is electrically connected with a terminal of each transistor that configures a controller for controlling a transistor of a readout circuit for each unit pixel. With respect to the multilayered wiring section in the pixel section A, although two layers are needed to couple the circuit, it is joined as the single wiring layer 4. That is, in the pixel section A, the wiring layer oriented in either a longitudinal or transverse direction is arranged via an insulation film so as to join the two wiring layers 4 and 6, together into the single wiring layer 4. The peripheral circuit section B has more wirings, including a shading film, than the pixel section A, and therefore, it is configured with the three wiring layers 4, 6 and 8.

Of all the wiring layers configuring the multilayered wiring section, the wiring layers 6 and 8, in which engraving of an interlayer insulation film to be described later reaches, do not have a wiring pattern positioned in the pixel section A (the wiring layer 6 is included in the wiring layer 4). Furthermore, the side end portion, adjacent to the pixel section A, of the peripheral circuit section B is formed into a stepwise wiring pattern such that the stepwise wiring pattern becomes more distant in sequence from the pixel section A as heading from a lower layer to an upper layer.

The interlayer insulation films 5, 7 and 9 are engraved uniformly in the pixel section A and the pixel section is thinner than in the peripheral circuit section B, and an engraved bottom portion is formed in such a manner to be close to a surface side of the photo diode 2. The engraved end portion of the interlayer insulation films 5, 7 and 9 are formed in a stepwise multi level form (to prevent a striation) in accordance with the stepwise wiring pattern described above. In addition, the degree of engraving for the interlayer insulation films 5, 7 and 9 is adjusted in such a manner that the focal point of a microlens 13 to be described later is set near a surface of the photo diode 2.

A protective film 10 and an interlayer film 11 are provided on the engraved interlayer insulation film 5 (on the bottom surface of the engraved portion T), and a color filter 12 and a microlens 13 are provided, in this order, on the interlayer film 11.

Each of the microlenses 13 is arranged facing a respective photo diode 2. The thickness of the interlayer film 11 is adjusted in accordance with the necessitated distance between the lens and substrate (the distance between the microlens 13 and the photo diode 2).

A method of manufacturing the solid-state image capturing device 20 according to Embodiment 1 with the structure described above will be described herein.

The solid-state image capturing device 20 according to Embodiment 1 is manufactured by (1) forming a multilayered wiring section, by (2) engraving interlayer insulation films 5, 7 and 9, and by (3) forming a color filter 12 and a microlens 13.

In the (1) formation of a multi layered wiring section, with respect to the wiring layer that the bottom portion of an engraved portion T reaches, a pattern is formed in accordance with the amount of engraving for the interlayer insulation films 5, 7 and 9 in such a manner that the wiring pattern is not arranged in the pixel section A. With respect to the wiring layer that the bottom portion of the engraved portion T reaches, a wiring pattern for self-alignment used as a mask at a self-alignment engraving is arranged simultaneously with the arrangement of other wiring patterns in the same layer in the peripheral circuit section B in such a manner to surround the pixel section A. The wiring pattern for self-alignment is formed into a stepwise wiring pattern such that the stepwise wiring pattern becomes more distant in sequence from the pixel section A as heading from a lower layer to an upper layer. A single-layered or multilayered film made of a material, such as Al, Cu, AlCu, TiN and Ti, can be used as a wiring layer. In addition, a film made of a material, such as BPSG (Boro-Phospho-Silicate Glass), HDP (High Density Plasma), USG (Undoped Silicate Glass) and PSG (Phospho-Silicate Glass) can be used as the interlayer insulation films 5, 7 and 9.

When (2) engraving interlayer insulation films, a resist pattern is formed subsequent to the forming of the last interlayer insulation film 9, which is subsequent to the forming of the multilayered wiring section. The interlayer insulation films in the pixel section A are etched with this resist pattern and the wiring pattern for self-alignment described above as a mask, so that the engraved portion T is formed. Engraved ends of the interlayer insulation films 5, 7 and 9 (external end in a plane view) are formed in a stepwise multi level form in accordance with the stepwise pattern of the wiring pattern for self-alignment described above. The amount of engraving for the interlayer insulation films 5, 7 and 9 is adjusted in such a manner that the focal point of the microlens 13 is set on or near the surface of the photo diode 2. The interlayer insulation film 5 is engraved so that the engraved bottom portion is flat for half the thickness of the interlayer insulation film.

When (3) forming a protective layer 10, a interlayer film 11, a color filter 12 and a microlens 13, the protective layer 10, interlayer film 11, color filter 12 and microlens 13, these layers are formed subsequent to engraving halfway into the interlayer insulation film 5. A light -transparent insulation film, such as silicon dioxide film and transparent resin film, can be used as the interlayer film 11. The thinner the interlayer film 11 is, the shorter the distance between the lens and substrate becomes and the easier it is to adjust the focal point.

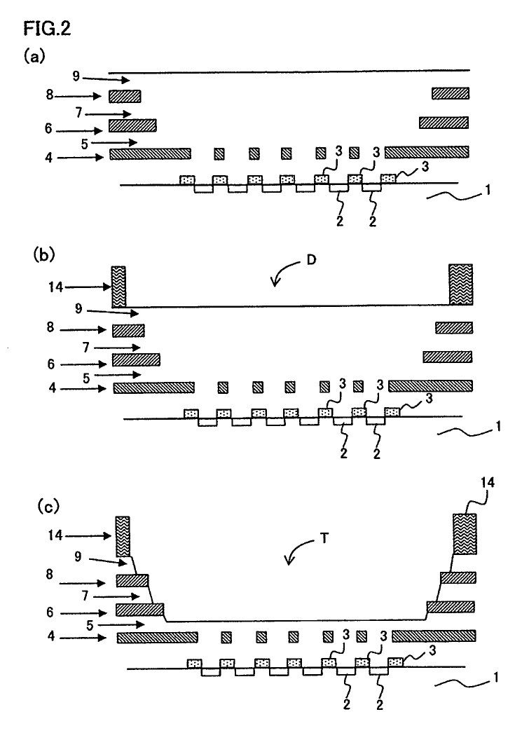

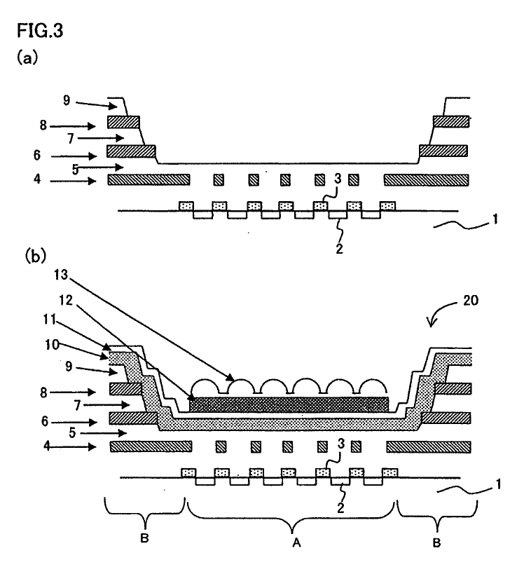

Next, the method of manufacturing the solid-state image capturing device 20 according to Embodiment 1 is further described in detail with respect to FIGS. 2 and 3.

FIG. 2(a)-FIG. 2(c), FIG. 3(a) and FIG. 3(b) are longitudinal cross-sectional views each explaining a step of manufacturing the solid-state image capturing device according to Embodiment 1. Note that manufacturing steps that are subsequent to a step of forming a multilayered wiring section are particularly shown in the figures.

The number of the lamination of the multilayered wiring section and the depth of the engraved portion are arbitrary in Embodiment 1. However, in this example, a case is described where three wiring layers 4, 6 and 8 and three interlayer insulation films 5, 7 and 9 are alternatively laminated on top of another, and the interlayer insulation films 5, 7 and 9 in the pixel section A are engraved up to halfway into the interlayer insulation film 5 that is in between the wiring layer 4 and the wiring layer 6 subsequent to forming the last interlayer insulation film 9.

First, as shown in FIG. 2(a), the wiring layer 4, the interlayer insulation film 5, the wiring layer 6, the interlayer insulation film 7, the wiring layer 8 and the interlayer insulation film 9 are formed in this order on a semiconductor substrate 1 with the photo diodes 2 and gate electrodes 3 formed thereon. The wiring layers 6 and 8 are not patterned in the region of the pixel section A. Instead, wiring patterns for self-alignment are arranged in the region of the peripheral circuit section B in such a manner to surround the pixel section A. The wiring patterns for self-alignment are formed in a stepwise pattern in such a manner that the wiring layer 8 is formed farther away from the end portion of the pixel section A than the wiring layer 6. In addition, with respect to a single layered wiring layer 4 in the pixel section A, the wiring layer oriented in either a longitudinal or transverse direction is arranged via an insulation film to put two wiring layers, including the wiring layers 4 and 6, together as the single wiring layer 4.

Next, as shown in FIG. 2(b), subsequent to forming the last interlayer insulation film 9, a resist pattern 14 is formed thereon with a photolithographic technique in such a manner that the region of the pixel section A is open. Dry etching is applied to the interlayer insulation film 5, 7 and 9 in the pixel section A up to halfway into the interlayer insulation film 5 using the resist pattern 14 as a mask, so that the engraved portion T is formed as shown in FIG. 2(c). An edge of the resist pattern 14 is located above the wiring pattern for self-alignment of the wiring layer 8, and self-alignment engraving with the wiring layers 6 and 8 allows the engraved ends of the interlayer insulation films 5, 7 and 9 to be formed as a stepwise multi level form in accordance with the stepwise patterns for the wiring layers 6 and 8 as shown in FIG. 2(c).

Further, as shown in FIG. 3(a), the resist pattern 14 is removed by 02 plasma ashing and the like. Subsequently, as shown in FIG. 3(b), a protective film 10 and an interlayer film 11 are formed in this order on the bottom surface of the engraved portion T of the interlayer insulation films 5, 7 and 9, and further, a color filter 12 and a microlens 13 are formed in this order on the interlayer film 11, thereby manufacturing the solid-state image capturing device 20 according to Embodiment 1.

According to Embodiment 1 as described above, engraving the interlayer insulation films 5, 7 and 9 in the pixel section A, in which a large number of unit pixels are arranged, significantly shortens the distance between the lens and substrate (the distance from the microlens 13 to the photo diode 2) while maintaining the multilayered wiring structure and improves optical characteristics in light receiving. Further, the engraved portion T of the interlayer insulation films 5, 7 and 9 is formed by the self-alignment engraving using the wiring pattern in such a manner that the engraved end (periphery) is formed in a stepwise multi level form widening upwardly, thereby reducing probability of an occurrence of a striation that indicates an inferior method of applying the interlayer insulation film.

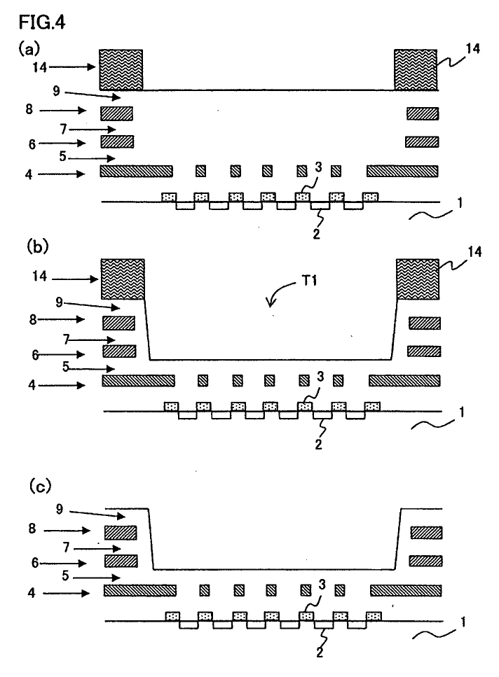

With respect to a method of engraving the interlayer insulation films, instead of having the stepwise multi level form for the wiring layers 6 and 8 to widen upwardly as described above, it is also possible to engrave the wiring layers 6 and 8 with their ends aligned using dry etching. Such a method will be described as an example of Embodiment 1 with respect to FIG. 4.

As shown in FIG. 4(a), subsequent to forming the interlayer insulation film 9, the resist pattern 14 is first formed on the interlayer insulation film 9 with a photolithographic technique. Next, as shown in FIG. 4(b), the interlayer insulation films 5, 7 and 9 are dry etched to form an engraved portion T1, and the resist pattern 14 is removed as shown in FIG. 4(c).

The method using dry etching for the wiring layers 6 and 8 with their ends aligned as described above may cause a difference in vertical levels that has an even and deep depth, which leads to a high probability of occurrence of a striation that indicates an inferior application of a microlens material by spin coating. Accordingly, it is considered difficult, in this case, to manufacture.

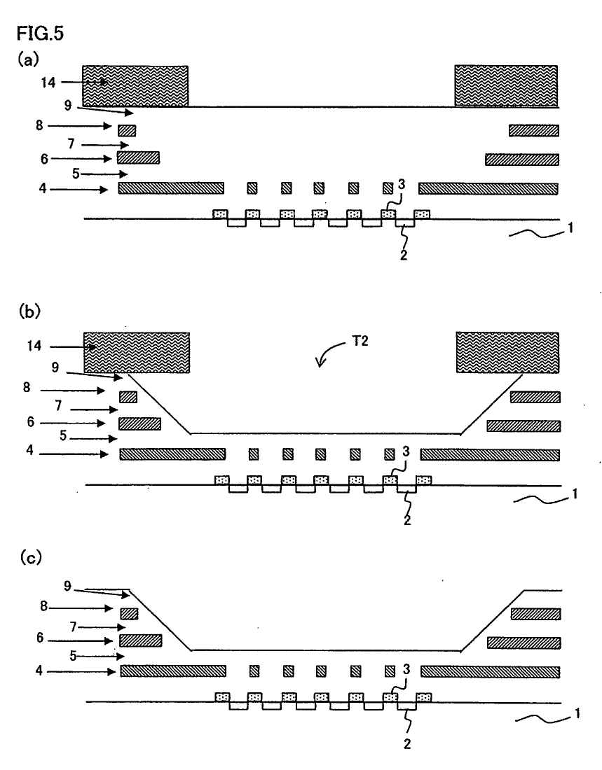

Therefore, in order to reduce the difference in vertical levels, it is conceivable to provide a method of forming a taper form of the engraved portion that is widened upwardly in the stepwise multi level form of the ends of the wiring layers 6 and 8 using wet etching and the like. Such a method is described using FIG. 5 as a variation of Embodiment 1.

As shown in FIG. 5(a), subsequent to forming the interlayer insulation film 9, the resist pattern 14 is formed on the interlayer insulation film 9 with a photolithographic technique. Next, as shown in FIG. 5(b), the interlayer insulation films are etched by wet etching and the like to form a engraved portion T2, and the resist pattern 14 is removed as shown in FIG. 5(a).

As described above, with the method utilizing wet etching in the stepwise multi level form of the ends of the wiring layers 6 and 8, the interlayer insulation film underneath the resist pattern is also etched in the transverse direction by isotropic etching, and therefore, a taper form can be obtained, thereby reducing probability of an occurrence of a striation. However, hydrogen fluoride is generally used for wet etching (aluminum or copper wirings will be etched in contact with hydrogen fluoride), and therefore, etching selectivity for the wirings is small. Wet etching extends in the transverse direction, and therefore, the etching location by the resist pattern 14 significantly changes. As a result, it is necessary to secure a distance margin (wiring unavailable region) between the engraved portion T2 and the wirings, resulting in a smaller region for wirings.

Therefore, in Embodiment 1, as described with respect to FIGS. 2 and 3, it is preferable to form the engraved portion T of the interlayer insulation film using the wiring pattern for self-alignment as a mask since more region will be available for wirings. (wiring available region) compared with this variation example.

### Embodiment 2

Embodiment 1 described above describes a case where, among the three wiring layers that configure the multilayered wiring section, the two wiring layers 6 and 8 which the engraving of the interlayer insulation film reaches do not have a wiring pattern arranged in the pixel section A while the wiring layer 4 which the engraving of the interlayer insulation film does not reach has a wiring pattern arranged in the pixel section A; and the side end portion, adjacent to the pixel section A, of the peripheral circuit section B is formed into a stepwise wiring pattern such that the stepwise wiring pattern becomes more distant in sequence from the pixel section A as heading from the lower wiring layer 6 to the upper wiring layer 8. Embodiment 2 describes a case where, among four wiring layers that configure a multilayered wiring section, two wiring layers 6 and 8, which the engraving of an interlayer insulation film reaches, do not have a wiring pattern arranged in a pixel section A while two wiring layers 4A and 4B, which the engraving of the interlayer insulation film does not reach, have a wiring pattern arranged in the pixel section A; and the side end portion, adjacent to the pixel section A, of the peripheral circuit section B is formed into a stepwise wiring pattern such that the stepwise wiring pattern becomes more distant in sequence from the pixel section A as heading from the lower wring layer 6 to the upper wiring layer 8.

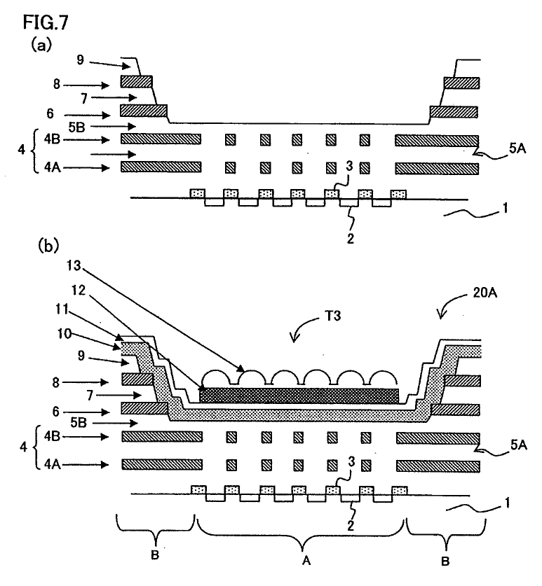

In FIG. 7(b), interlayer insulation film 5B, 7 and 9 are engraved uniformly in the pixel section A and are thinner than the peripheral circuit section B, and an engraved bottom portion is formed in such a manner to be close to a surface side of a photo diode 2. The engraved end portion of the interlayer insulation films 5B, 7 and 9 are formed in a stepwise multi level form in accordance with the stepwise wiring pattern described above. In addition, the degree of engraving for the interlayer insulation films 5B, 7 and 9 is adjusted in such a manner that the focal point of a microlens 13 to be described later is set near a surface of the photo diode 2.

A protective film 10 and an interlayer film 11 are provided on the engraved interlayer insulation film 5B (on the bottom surface inside the engraved portion T3), and a color filter 12 and a microlens 13 are provided in this order on the interlayer film 11.

Each of the microlenses 13 is arranged facing a respective photo diode 2. The thickness of the interlayer film 11 is adjusted in accordance with the necessitated distance between the lens and substrate (the distance between the microlens 13 and the photo diode 2).

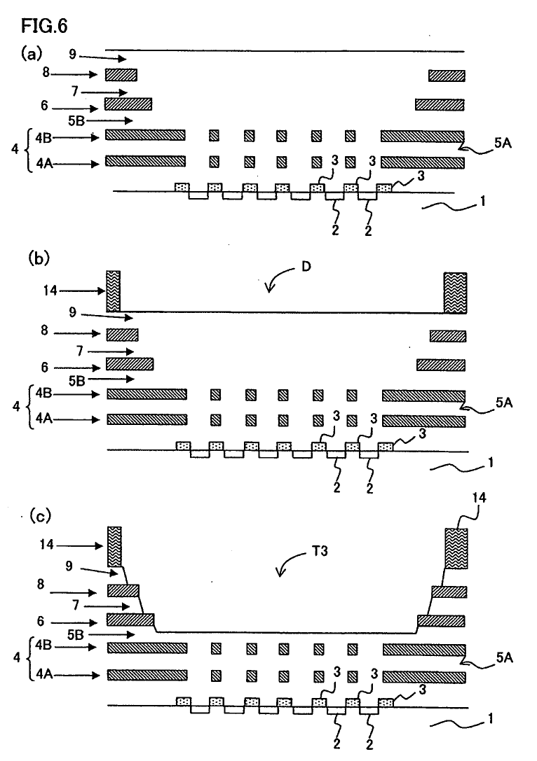

A method of manufacturing the solid-state image capturing device 20A according to Embodiment 2 with the structure described above will be described herein with reference to FIGS. 6 and 7.

FIG. 6(a)-FIG. 6(c), FIG. 7(a) and FIG. 7(b) are longitudinal cross-sectional views each explaining a step of manufacturing the solid-state image capturing device according to Embodiment 2. Note that manufacturing steps that are subsequent to a step of forming a multilayered wiring section are particularly shown in the figures.

In Embodiment 2, it will be described a case where four wiring layers 4A, 4B, 6 and 8 and four interlayer insulation films 5A, 5B, 7 and 9 are alternatively laminated on top of another, and the interlayer insulation films 5B, 7 and 9 in the pixel section A are engraved halfway into the interlayer insulation film 5B that is in between the wiring layer 4B and the wiring layer 6 subsequent to forming the last interlayer insulation film 9.

First, as shown in FIG. 6(a), the wiring layer 4A, the interlayer insulation film 5A, the wiring layer 4B, the interlayer insulation film 5B, the wiring layer 6, the interlayer insulation film 7, the wiring layer 8 and the interlayer insulation film 9 are formed in this order on a semiconductor substrate 1 with the photo diodes 2 and gate electrodes 3 formed thereon. The wiring layers 6 and 8 are not patterned in the region of the pixel section A. Instead, wiring patterns for self-alignment are arranged in the region of the peripheral circuit section B in such a manner to surround the pixel section A. The wiring patterns for self-alignment are formed in a stepwise pattern in such a manner that the wiring layer 8 is formed farther away from the end portion of the pixel section A than the wiring layer 6. That is, in the pixel section A, the two wiring layers 4A and 4B are oriented in either a longitudinal or transverse direction via an insulation layer to put three or four wiring layers, including the wiring layers 6 and 8, together into two wiring layers.

Next, as shown in FIG. 6(b), subsequent to forming the last interlayer insulation film 9, a resist pattern 14 is formed thereon with a photolithographic technique in such a manner that the region of the pixel section A is open (opening D). Dry etching is applied to the interlayer insulation film 5B, 7 and 9 in the pixel section A up to halfway into the interlayer insulation film 5B using the resist pattern 14 as a mask, so that the engraved portion T3 is formed as shown in FIG. 6(o). An edge of the resist pattern 14 is located above the wiring pattern for self-alignment of the wiring layer 8, and self-alignment engraving with the wiring layers 6 and 8 allows the engraved ends of the interlayer insulation films 5B, 7 and 9 to be formed as a stepwise multi level form in accordance with the stepwise patterns for the wiring layers 6 and 8 as shown in FIG. 6(c).

Further, as shown in FIG. 7(a), the resist pattern 14 is removed by O₂ plasma ashing and the like. Subsequently, as shown in FIG. 7(b), a protective film 10 and an interlayer film 11 are formed in this order on the bottom surface of the engraved portion T3 of the interlayer insulation films 5B, 7 and 9, and further, a color filter 12 and a microlens 13 are formed in this order on the interlayer film 11, thereby manufacturing the solid-state image capturing device 20A according to Embodiment 2.

In Embodiment 2 described above, it has been described a case where, among the four wiring layers that configure the multilayered wiring section, the two wiring layers 6 and 8, which the engraving of the interlayer insulation film reaches, do not have a wiring pattern arranged in the pixel section A while the wiring layers 4A and 4B which the engraving of the interlayer insulation film does not reach have wiring patterns arranged in the pixel section A; and the end portion of the peripheral circuit section B on the side next to the pixel section A is formed in a stepwise wiring pattern in such a manner that each end portion of the wiring layers becomes farther away from the pixel section A from the lower wiring layer 6 to the upper wiring layer 8 as the higher the layer is. However, without being limited to this, there can be a case where, of all the four wiring layers that configure the multilayered wiring section, only the wiring layer 8, which the engraving of the interlayer insulation film reaches, does not have a wiring pattern arranged in the pixel section A while the rest of the three wiring layers 4A, 4B and 6 which the engraving of the interlayer insulation film does not reach have wiring patterns arranged in the pixel section A.

### Embodiment 3

In embodiment 1, it has been described a case where, among the three wiring layers that configure the multilayered wiring section, the wiring layer 8 which the engraving of the interlayer insulation film reaches does not have a wiring pattern arranged in the pixel section A while the wiring layer 4 which the engraving of the interlayer insulation film does not reach has a wiring pattern arranged in the pixel section A. However, in Embodiment 3, it will be described a case where, among the three wiring layers that configure the multilayered wiring section, the wiring layer 8, which the engraving of the interlayer insulation film reaches, does not have a wiring pattern arranged in the pixel section A while the rest of the two wiring layers 4 and 6A, which the engraving of the interlayer insulation film, does not reach have wiring patterns arranged in the pixel section A.

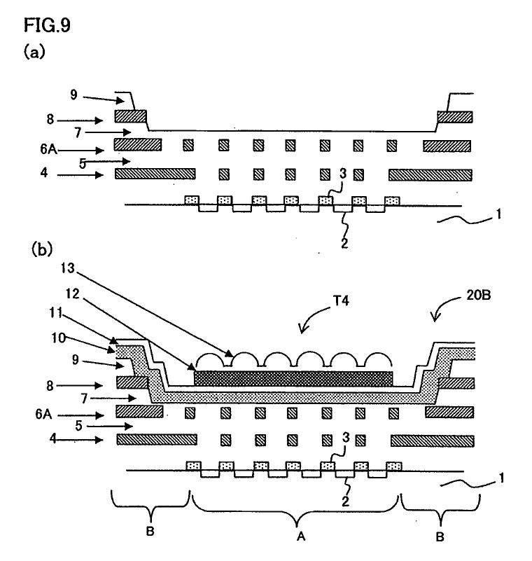

In FIG. 9(b), interlayer insulation film 7 and 9 are engraved uniformly in the pixel section A and are thinner than the peripheral circuit section B, and an engraved bottom portion is formed in such a manner to be close to a surface side of a photo diode 2. In addition, the degree of engraving for the interlayer insulation films 7 and 9 is adjusted in such a manner that the focal point of a microlens 13 to be described later is set near a surface of the photo diode 2.

A protective film 10 and an interlayer film 11 are provided on the engraved interlayer insulation film 7 (on the bottom surface inside the engraved portion T4), and a color filter 12 and a microlens 13 are provided in this order on the interlayer film 11.

Each of the microlenses 13 is arranged facing a respective photo diode 2. The thickness of the interlayer film 11 is adjusted in accordance with the necessitated distance between the lens and substrate (the distance between the microlens 13 and the photo diode 2).

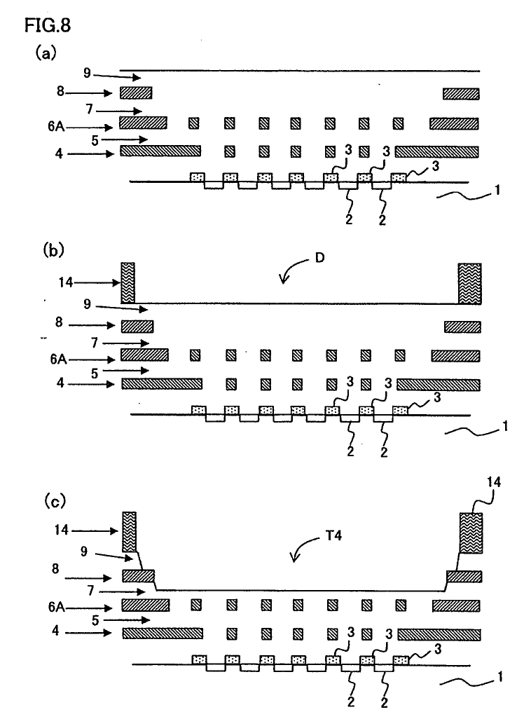

A method of manufacturing the solid-state image capturing device 20B according to Embodiment 3 with the structure described above will be described herein with reference to FIGS. 8 and 9.

FIG. 8(a)-FIG. 8(c), FIG. 9(a) and FIG. 9(b) are longitudinal cross-sectional views each explaining a step of manufacturing the solid-state image capturing device according to Embodiment 3. Note that manufacturing steps that are subsequent to a step of forming a multilayered wiring section are particularly shown in the figures.

In Embodiment 3, it will be described a case where three wiring layers 4, 6A and 8 and three interlayer insulation films 5, 7 and 9 are alternatively laminated on top of another, and the interlayer insulation films 7 and 9 in the pixel section A are engraved up to halfway into the interlayer insulation film 7 that is in between the wiring layer 6A and the wiring layer 8 subsequent to forming the last interlayer insulation film 9.

First, as shown in FIG. 8(a), the wiring layer 4, the interlayer insulation film 5, the wiring layer 6A, the interlayer insulation film 7, the wiring layer 8, and the interlayer insulation film 9 are formed in this order on a semiconductor substrate 1 with the photo diodes 2 and gate electrodes 3 formed thereon. The wiring layer 8 is not patterned in the region of the pixel section A. Instead, a wiring pattern for self-alignment is arranged in the region of the peripheral circuit section B in such a manner to surround the pixel section A. That is, in the pixel section A, the two wiring layers 4 and 6A are oriented in either a longitudinal or transverse direction via an insulation layer to put three wiring layers including the wiring layer 8 together into two wiring layers.

Next, as shown in FIG. 8(b), subsequent to forming the last interlayer insulation film 9, a resist pattern 14 is formed thereon with a photolithographic technique in such a manner that the region of the pixel section A is open (opening D). Dry etching is applied to the interlayer insulation film 7 and 9 in the pixel section A up to halfway into the interlayer insulation film 7 using the resist pattern 14 as a mask, so that the engraved portion T4 is formed as shown in FIG. 8(c). An edge of the resist pattern 14 is located above the wiring pattern for self-alignment of the wiring layer 8, and self-alignment engraving with the wiring layer 8 allows the engraved ends of the interlayer insulation film 7 and 9 to be shallow.

Further, as shown in FIG. 9(a), the resist pattern 14 is removed by O₂ plasma ashing and the like. Subsequently, as shown in FIG. 9(b), a protective film 10 and an interlayer film 11 are formed in this order on the bottom surface of the engraved portion T4 of the interlayer insulation films 7 and 9, and further, a color filter 12 and a microlens 13 are formed in this order on the interlayer film 11, thereby manufacturing the solid-state image capturing device 20B according to Embodiment 3.

### Embodiment 4

In Embodiment 4, it will be described an electronic information device having, for example, a digital camera (e.g., digital video camera, digital still camera), an image input camera (e.g., monitoring camera, door intercom camera, car-mounted camera such as a car-mounted backside monitoring camera, camera for television telephone and camera for cell phone), and an image input device (e.g., scanner, facsimile and cell phone device equipped with camera) using at least any one of solid-state image capturing devices 20 and 20A and 20B according to Embodiments 1 to 3.

The electronic information device according to Embodiment 4 includes at least one of: a memory section (e.g., recording media) for data-recording high-quality image data obtained from any one of the solid-state image capturing devices 20, 20A and 20B after a predetermined signal processing for recording; a display section (e.g., liquid crystal display device) for displaying the image data on a display screen (e.g., liquid crystal display screen) after a predetermined signal processing is performed; a communication section (e.g., transmitting and receiving device) for performing a communication processing on the image data after a predetermined signal processing is performed for communicating; and an image output section for printing (typing out) and outputting (printing out) the image data.

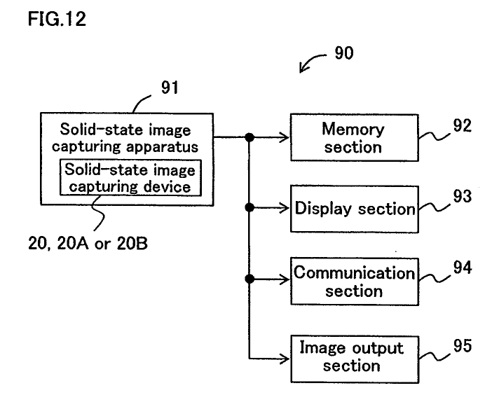

FIG. 12 is a block diagram showing an exemplary schematic structure of an electronic information device according to Embodiment 4 of the present invention using the solid-state image capturing apparatus as an image capturing section, the electronic information device including any one of the solid-state image capturing devices 20, 20A and 20G in Embodiments 1-3.

The electronic information device 90 according to Embodiment 9 in FIG. 23 includes at least one of the following: an solid-state image capturing apparatus 91 which performs various signal processes for high-quality image capturing signals with no image quality deterioration obtained by using any one of the solid-state image capturing devices 20, 20A and 20B according to Embodiments 1-8 as an image input device for an image capturing section in order to obtain color image signals; a memory section 92 (e.g., recording media) for data-recording color image signals from the solid-state image capturing apparatus 91 after a predetermined signal process for recording; a display section 93 (e.g., liquid crystal display device) for displaying the color image signals on a display screen (e.g., liquid crystal display screen) after a predetermined signal process is performed; a communication section 94 (e.g., transmitting and receiving device) for communicating image data after a predetermined signal process is performed on the color image signals; and an image output section 95 for printing (typing out) and outputting (printing out) the color image signals.

Therefore, according to Embodiment 4 of the present invention, based on the color image signals from the solid-state image capturing apparatus 91, the color image signals can be: displayed on a display screen finely, printed out (printing) on a sheet of paper using the image output section 95, communicated finely as communication data via a wire or a radio; stored finely at the memory section 92 by performing a predetermined data compression process; and various data processes can be finely performed.

According to Embodiments 1-3 described above, in the solid-state image capturing devices 20, 20A or 20B, the interlayer insulation films in the pixel section A are uniformly engraved, the wiring layers which the engraving of the interlayer insulation film reaches do not have a wiring pattern arranged in the pixel section A, and the wiring pattern for self-alignment is arranged in the peripheral circuit section B on the side next to the pixel section A. The wiring pattern for self-alignment is formed into a stepwise wiring pattern such that the stepwise wiring pattern becomes more distant in sequence from the pixel section A as heading from a lower layer to an upper layer. The stepwise multi level steps of the wiring layers are formed in the end portion of the engraved interlayer insulation films by the self-alignment engraving. The microlenses 13 are formed in the engraved portion of the interlayer insulation film. Such a configuration allows of obtaining a multilayered wiring structure while significantly shortening the distance between the lens and the substrate in a simple manner, thereby improving condensation of light and optical characteristics.

In Embodiments 1-4 described above, a multilayered wiring section is configured with a plurality of wiring layers being laminated via interlayer insulation films in between the wiring layers. However, without being limited to this configuration, layers of air can be configured instead of the interlayer insulation films. Alternatively, layers of air can be configured instead of some of the interlayer insulation films. For example, in a case where a multilayered wiring section is configured with a plurality of wiring layers laminated via interlayer insulation films in between the wiring layers, the interlayer insulation films may be etched (or the interlayer insulation films may be removed) and the plurality of wiring layers may be configured (constructed) by being supported by contact sections on a semiconductor substrate or on a semiconductor region formed on the substrate as well as by contact sections in between the wiring sections, so that the multilayered wiring section are configured with layers of air provided in between the wiring layers. In this case, the layers of air has dielectric constant significantly lower than that of the interlayer insulation film, and parasitic capacitance occurred between wiring layers are significantly reduced, thereby obtaining an effect to significantly reduce signal collapse (signal dulling) due to signal transferring between the wiring layers. For example, with respect to the region where a microlens is provided, the interlayer insulation film can remain laminated, so that the color film and microlens can be provided thereon. In the peripheral region other than the region where the microlens is provided, a layer of air can be provided instead of the interlayer insulation film.

Although not specifically explained in Embodiments 1-4 described above, a multilayered wiring section having a plurality of wiring layers laminated via respective interlayer insulation films in between is provided on a semiconductor substrate (or a semiconductor region formed on the substrate) where a plurality of light receiving sections for photoelectrically converting a subject light are arranged in matrix in a pixel section; and the interlayer insulation films in a pixel section are evenly engraved, so that the pixel section of the substrate is thinner than a peripheral circuit section; and a plurality of light receiving sections and respective microlenses facing with each other are arranged on the bottom surface of the engraved portion of the interlayer insulation film. Accordingly, the objective of the present invention, which is obtaining a multilayered wiring structure while significantly shortening the distance between the lens and the substrate in a simple manner, thereby improving condensation of light and optical characteristics, is achieved.

In addition, Embodiment 1 described above will be further described herein. In a peripheral circuit section B, an interlayer insulation film (not shown), a wiring layer 4, an interlayer insulation film 5, a wiring layer 6, an interlayer insulation film 7, a wiring layer 8, and an interlayer insulation film 9 are provided as a multilayered wiring section in this order from the bottom; and only a wiring layer 4 is provided in a pixel section A; and the interlayer insulation films 5, 7 and 9 are engraved up to halfway into the interlayer insulation film 5 as an engraved portion T. Further, Embodiment 3 described above will be more specifically described herein In a peripheral circuit section B, an interlayer insulation film (not shown), a wiring layer 4, an interlayer insulation film 5, a wiring layer 6A, an interlayer insulation film 7, a wiring layer 8, and an interlayer insulation film 9 are provided as a multilayered wiring section in this order from the bottom; and only wiring layers 4 and 6A are provided in a pixel section A; and the interlayer insulation films 7 and 9 are engraved up to halfway into the interlayer insulation film 7 as an engraved portion T4. Further, Embodiment 2 described above will be more specifically described herein. In a peripheral circuit section B, an interlayer insulation film (not shown), a wiring layer 4A, an interlayer insulation film 5A, a wiring layer 4B, an interlayer insulation film 5B, a wiring layer 6, an interlayer insulation film 7, a wiring layer 8 and an interlayer insulation film 9 are provided as a multilayered wiring section in this order from the bottom; and only wiring layers 4A and 4B are provided in a pixel section A; and the interlayer insulation films 5B, 7 and 9 are engraved up to halfway into the interlayer insulation film 5B as an engraved portion T3.

Besides the descriptions above, in a peripheral circuit section B, an interlayer insulation film (not shown), a wiring layer 4A, an interlayer insulation film 5A, a wiring layer 4B, an interlayer insulation film 5B, a wiring layer 6, an interlayer insulation film 7, a wiring layer 8 and an interlayer insulation film 9 can be provided as a multilayered wiring section in this order from the bottom; and only a wiring layer 4A can be provided in a pixel section A; and the interlayer insulation films 5B, 6, 8 and 9 can be engraved up to halfway into the interlayer insulation film 5B as an engraved portion. In addition, besides the description above, in a peripheral circuit section B, an interlayer insulation film (not shown), a wiring layer 4A, an interlayer insulation film 5A, a wiring layer 4B, an interlayer insulation film 5B, a wiring layer 6, an interlayer insulation film 7, a wiring layer 8 and an interlayer insulation film 9 can be provided as a multilayered wiring section in this order from the bottom; and only wiring layers 4A, 4B and 6 can be provided in a pixel section A; and the interlayer insulation films 7 and 9 can be engraved up to halfway into the interlayer insulation film 7 as an engraved portion. That is, in a peripheral circuit section B, a first wiring layer—Nth (an integer of greater or equal to 3) wiring layer have only to be provided as a multilayered wiring section with a first interlayer insulation film—an (N+1)th interlayer insulation film inserted respectively in between; and wiring layers of fewer number than the Nth layer have only to be provided in the pixel section A; and interlayer insulation films that do not include wiring layers have only to be engraved as an engraved portion.

As described above, the present invention is exemplified by the use of its preferred Embodiments 1 to 4. However, the present invention should not be interpreted solely based on Embodiments 1 to 4 described above. It is understood that the scope of the present invention should be interpreted solely based on the claims. It is also understood that those skilled in the art can implement equivalent scope of technology, based on the description of the present invention and common knowledge from the description of the detailed preferred Embodiments 1 to 4 of the present invention. Furthermore, it is understood that any patent, any patent application and any references cited in the present specification should be incorporated by reference in the present specification in the same manner as the contents are specifically described therein.

### Industrial Applicability

According to the present invention, in the field of a solid-state image capturing device, such as CMOS image sensor, and a manufacturing method of the solid-state image capturing device, and an electronic information device, such as digital camera and cell phone device equipped with camera, using the solid-state image capturing device as an image capturing section thereof, interlayer insulation films in a pixel section are engraved, so that such a configuration allows of obtaining a multilayered wiring structure while significantly shortening the distance between the lens and the substrate in a simple manner, thereby improving optical characteristics. In addition, self-alignment engraving using a wiring pattern allows of forming an engraved end in a stepwise multi level form, thereby reducing probability of an occurrence of a striation. Further, self-alignment engraving allows of reducing a region where wiring pattern can not be formed in the peripheral section of the pixel section (allows of reducing the distance margin between the engraved portion and the wiring).

Various other modifications will be apparent to and can be readily made by those skilled in the art without departing from the scope and spirit of this invention. Accordingly, it is not intended that the scope of the claims appended hereto be limited to the description as set forth herein, but rather that the claims be broadly construed.

What is claimed is:

1. A solid-state image capturing device, in which a multilayered wiring section having a plurality of wiring layers laminated via respective interlayer insulation films in between is provided on a semiconductor substrate or a semiconductor region formed on the substrate where a plurality of light receiving sections for photoelectrically converting a subject light are arranged in a matrix in a pixel section; and the interlayer insulation films in a pixel section are evenly engraved, so that the pixel section of the substrate is thinner than a peripheral circuit section; and microlenses are arranged to face the plurality of light receiving section respectively on the bottom surface of the engraved portion of the interlayer insulation film.

2. A solid-state image capturing device according to claim 1, wherein a layer of air is provided instead of at least some of the interlayer insulation films.

3. A solid-state image capturing device according to claim 2, wherein the plurality of wiring layers are supported by contact sections on the semiconductor substrate or the semiconductor region formed on the substrate and by contact sections between the wiring sections, so that the plurality of wiring layers are configured in the multilayered wiring section.

4. A solid-state image capturing device according to claim 1, wherein the amount of engraving for the interlayer insulation film is adjusted in such a manner that the focal point of the microlens is set on a surface of the light receiving section.

5. A solid-state image capturing device according to claim 1, wherein a wiring pattern is arranged in a depth region of the interlayer insulation films engraved only from a periphery of the pixel section to a peripheral section in a plane view.

6. A solid-state image capturing device according to claim 1, wherein the wiring layers, which engraving for the interlayer insulation films reach, are formed into a stepwise wiring pattern such that an end portion, adjacent to the pixel section, of the peripheral section becomes more distant in sequence from the pixel section as heading from a lower layer to an upper layer.

7. A solid-state image capturing device according to claim 5, wherein the wiring layers, which engraving for the interlayer insulation films reach, are formed into a stepwise wiring pattern such that an end portion, adjacent to the pixel section, of the peripheral section becomes more distant in sequence from the pixel section as heading from a lower layer to an upper layer.

8. A solid-state image capturing device according to claim 6, wherein a periphery end of the engraved portion of the interlayer insulation films in a plane view is formed in a stepwise multi level form in accordance with the stepwise wiring pattern.

9. A solid-state image capturing device according to claim 7, wherein a periphery end of the engraved portion of the interlayer insulation films in a plane view is formed in a stepwise multi level form in accordance with the stepwise wiring pattern.

10. A solid-state image capturing device according to claim 1, wherein a periphery end of the engraved portion of the interlayer insulation films is formed in a taper form in such a manner that the engraved portion in a cross-sectional form is widened upwardly.

11. A solid-state image capturing device according to claim 1, wherein a protective film and an interlayer film are formed in this order on the bottom surface of the engraved portion of the interlayer insulation films; and color filters for respective colors are provided in such a manner to face the respective plurality of light receiving sections: and the microlenses are provided In such a manner to face the respective plurality of light receiving sections and the respective color filters for respective colors.

12. A solid-state image capturing device according to claim 1, wherein, in the peripheral section, a first interlayer insulation film, a first wiring layer, a second interlayer insulation film, a second wiring layer, a third interlayer insulation film, a third wiring layer and a fourth interlayer insulation film are provided in this order from the bottom as the multilayered wiring section; and only the first wiring layer is provided in the pixel section; and the second interlayer insulation film, the third interlayer insulation film and the fourth interlayer insulation film are engraved up to halfway into the second interlayer insulation film as the engraved portion.

13. A solid-state image capturing device according to claim 1, wherein, in the peripheral section, a first interlayer insulation film, a first wiring layer, a second interlayer insulation film, a second wiring layer, a third interlayer insulation film, a third wiring layer and a fourth interlayer insulation film are provided in this order from the bottom as the multilayered wiring section; and only the first wiring layer and the second wiring layer are provided in the pixel section; and the third interlayer insulation film and the fourth interlayer insulation film are engraved up to halfway into the third interlayer insulation film as the engraved portion.

14. A solid-state image capturing device according to claim 1, wherein, in the peripheral section, a first interlayer insulation film, a first wiring layer, a second interlayer insulation film, a second wiring layer, a third interlayer insulation film, a third wiring layer, a fourth interlayer insulation film, a fourth wiring layer and a fifth interlayer insulation film are provided in this order from the bottom as the multilayered wiring section; and only the first wiring layer and the second wiring layer are provided in the pixel section; and the third interlayer insulation film, the fourth interlayer insulation film and the fifth interlayer insulation film are engraved up to halfway into the third interlayer insulation film as the engraved portion.

15. A solid-state image capturing device according to claim 1, wherein, in the peripheral section, a first interlayer insulation film, a first wiring layer, a second interlayer insulation film, a second wiring layer, a third interlayer insulation film, a third wiring layer, a fourth interlayer insulation film, a fourth wiring layer and a fifth interlayer insulation film are provided in this order from the bottom as the multilayered wiring section; and only the first wiring layer is provided in the pixel section; and the second interlayer insulation film, the third interlayer insulation film, the fourth interlayer insulation film and the fifth interlayer insulation film are engraved up to halfway into the second interlayer insulation film as the engraved portion.

16. A solid-state image capturing device according to claim 1, wherein, in the peripheral section, a first interlayer insulation film, a first wiring layer, a second interlayer insulation film, a second wiring layer, a third interlayer insulation film, a third wiring layer, a fourth interlayer insulation film, a fourth wiring layer and a fifth:interlayer insulation film are provided in this order from the bottom as the multilayered wiring section; and only the first wiring layer, the second wiring layer and the third wiring layer are provided in the pixel section; and the fourth interlayer insulation film and the fifth interlayer insulation film are engraved up to halfway into the fourth interlayer insulation film as the engraved portion.

17. A solid-state image capturing device according to claim 1, wherein, in the peripheral section, a first wiring layer to an Nth (an integer of greater or equal to 3) wiring layer are provided as the multilayered wiring section with a first interlayer insulation film to an (N+1)th interlayer insulation film inserted respectively in between; and wiring layers of fewer number than N layers are provided in the pixel section; and interlayer insulation films that do not include the wiring layers are engraved as the engraved portion.

18. A solid-state image capturing device according to claim 1, wherein each of the wiring layers in the pixel section is arranged in such a manner that each wiring layer is divided and put together via an insulation film in a longitudinal direction and/or a transverse direction.

19. A method for manufacturing a solid-state image capturing device, comprising:
a multilayered wiring section forming step of forming a multilayered wiring section by laminating a plurality of wiring layer and interlayer insulation films alternatively on top of another on a semiconductor substrate or a semiconductor region formed on the substrate where a plurality of light receiving sections for photoelectrically converting a subject light are arranged in matrix in a pixel section;
an interlayer insulation film engraving step of engraving a region of the interlayer insulation films that do not include the wiring layers in the pixel section evenly so that the interlayer insulation films in the pixel section are formed thinner than a peripheral section of the pixel section; and
a microlens forming step of forming microlenses on the bottom surface of the engraved portion of the interlayer insulation film in such a manner that the microlenses face the respective plurality of light receiving sections.

20. A method for manufacturing a solid-state image capturing device according to claim 19, wherein the multilayered wiring section forming step forms a wiring pattern in a depth region of the interlayer insulation films engraved only from an periphery of the pixel section to a peripheral section in a plane view.

21. A method for manufacturing a solid-state image capturing device according to claim 19, wherein, in the multilayered wiring section forming step, the wiring layers, which engraving for the interlayer insulation films reach, are formed into a stepwise wiring pattern such that the stepwise wiring pattern becomes more distant in sequence from the pixel section as heading from a lower layer to an upper layer.

22. A method for manufacturing a solid-state image capturing device according to claim 20, wherein, in the multilayered wiring section forming step, the wiring layers, which engraving for the interlayer insulation films reach, are formed into a stepwise wiring pattern such that the stepwise wiring pattern becomes more distant in sequence from the pixel section as heading from a lower layer to an upper layer.

23. A method for manufacturing a solid-state image capturing device according to claim 21, wherein, in the interlayer insulation film engraving step, the interlayer insulation films are engraved by self-alignment with the stepwise wiring pattern as a mask, so that a periphery end of the engraved portion of the interlayer insulation films in a plane view is formed in a stepwise multi level form in accordance with the stepwise wiring pattern.

24. A method for manufacturing a solid-state image capturing device according to claim 22, wherein, in the interlayer insulation film engraving step, the interlayer insulation films are engraved by self-alignment with the stepwise wiring pattern as a mask, so that a periphery end of the engraved portion of the interlayer insulation films in a plane view is formed in a stepwise multi level form in accordance with the stepwise wiring pattern.

25. A method for manufacturing a solid-state image capturing device according to claim 19, wherein, in the interlayer insulation film engraving step, the amount of engraving is adjusted in such a manner that the focal point of the microlens is set on a surface of the light receiving section.

26. A method for manufacturing a solid-state image capturing device according to claim 19, wherein a periphery end of the engraved portion of the interlayer insulation films is etched in the longitudinal and transverse directions by isotropic etching to form a taper form in such a manner that the engraved portion in a cross-sectional form is widened upwardly.

27. A method for manufacturing a solid-state image capturing device according to claim 19, further including a step of forming a protective film and an interlayer film in this order on the bottom surface of the engraved portion of the interlayer insulation film subsequent to the interlayer insulation film engraving step, and a color filter forming step of forming color filters for respective colors on the interlayer film in such a manner to face the respective plurality of light receiving sections; and
wherein the microlens forming step forms the microlenses on the color filters in such a manner to face the respective plurality of light receiving sections and the respective color filters for respective colors.

28. A method for manufacturing a solid-state image capturing device according to claim 19, wherein the interlayer insulation film engraving step engraves an interlayer insulation film by dry etching or wet etching.

29. An electronic information device using the solid-state image capturing device according to claim 1 as an image input section thereof.
